(19) United States
(12) Patent Application Publication
(10) Pub. No.: US 2026/0033551 A1
(43) Pub. Date: Feb. 5, 2026

(54) AEROSOL GENERATING DEVICE

(71) Applicant: KT&G CORPORATION, Daejeon (KR)

(72) Inventors: Sang Kyu PARK, Seoul (KR); Sang Joon Kim, Yongin-si (KR); Jae Min Lee, Siheung-si (KR); Se Hwan Jung, Anyang-si (KR); Byung Sung Cho, Gwangmyeong-si (KR)

(73) Assignee: KT&G CORPORATION, Daejeon (KR)

(21) Appl. No.: 19/280,476

(22) Filed: Jul. 25, 2025

(30) Foreign Application Priority Data
Aug. 1, 2024 (KR) 10-2024-0102732

(51) Int. Cl. A24F 40/51; A24F 40/20; A24F 40/53; A24F 40/57

(52) U.S. Cl. CPC A24F 40/51; A24F 40/20; A24F 40/53; A24F 40/57

(57) ABSTRACT

An aerosol generating device according to an embodiment includes a cavity into which an aerosol generating article is inserted, an article detection sensor configured to detect a change in capacitance of the cavity and output a signal, a heater configured to heat at least a part of the aerosol generating article inserted into the cavity, and a control unit electrically connected to the article detection sensor and the heater, wherein the control unit is configured to compare the signal output from the article detection sensor with a preset reference value and generate a detection value, and determine that the aerosol generating article is inserted into the cavity when the detection value is included within a preset range.

### CROSS-REFERENCE TO RELATED APPLICATION

This application is based on and claims priority under 35 U.S.C. § 119 to Korean Patent Application No. 10-2024-0102732, filed on Aug. 1, 2024, in the Korean Intellectual Property Office, the disclosure of which is incorporated by reference herein in its entirety.

### BACKGROUND

### 1. Field

The disclosure relates to an aerosol generating device capable of determining whether an aerosol generating article is inserted.

### 2. Description of the Related Art

Recently, the demand for alternative methods for overcoming the shortcomings of general cigarettes has increased. For example, there is an increasing demand for a system for generating aerosols by heating a cigarette or an aerosol generating material by using an aerosol generating device, rather than by burning cigarettes.

When an aerosol generating article is inserted into an accommodation space, an aerosol generating device may heat the aerosol generating article according to a preset temperature profile. The temperature profile may mean temperature change data of a heater or an aerosol generating article during a smoking operation.

### SUMMARY

A sensor detecting whether an aerosol generating article is inserted may be affected by temperature or humidity.

In particular, in an aerosol generating device, when an aerosol generating article is inserted into a cavity, and when a heater is heated, a sensor may be exposed to a high-temperature environment, and the sensor may be exposed to a humid environment by an aerosol generated from the aerosol generating article.

Various embodiments relate to an aerosol generating device capable of compensating for a detection value obtained through a sensor according to an operating environment of the sensor detecting whether an aerosol generating article is inserted.

Additional aspects will be set forth in part in the description which follows and, in part, will be apparent from the description, or may be learned by practice of the presented embodiments.

An aerosol generating device according to an embodiment includes a cavity into which an aerosol generating article is inserted, an article detection sensor configured to detect a change in capacitance of the cavity and output a signal, a heater configured to heat at least a part of the aerosol generating article inserted into the cavity, and a control unit electrically connected to the article detection sensor and the heater, wherein the control unit is configured to compare the signal output from the article detection sensor with a preset reference value and generate a detection value, and determine that the aerosol generating article is inserted into the cavity when the detection value is included within a preset range.

The aerosol generating device may further include a temperature sensor configured to detect a ambient temperature around the article detection sensor, and a memory storing a compensation value for compensating for the detection value, wherein the control unit is electrically connected to the temperature sensor to obtain the ambient temperature of the article detection sensor from the temperature sensor, when the signal output from the article detection sensor is obtained, is configured to identify a temperature at a time when the signal is obtained, extract a compensation value corresponding to the temperature from the memory, and compensate for the detection value based on the extracted compensation value.

The compensation value may be a compensation value of the signal output from the article detection sensor according to the temperature.

The compensation value may ensure that a capacitance value of the cavity detected by the article detection sensor remains lower than the reference value while the aerosol generating article is not inserted into the cavity.

The compensation value may be a compensation value of the reference value output from the article detection sensor according to the temperature.

The aerosol generating device may further include a humidity sensor configured to detect a ambient humidity around the article detection sensor, and a memory storing a compensation value for compensating for the detection value, wherein the control unit is electrically connected to the humidity sensor to obtain the ambient temperature of the article detection sensor from the humidity sensor, and when the signal output from the article detection sensor is obtained, is configured to identify a humidity at a time when the signal is obtained, extract a compensation value corresponding to the temperature and the humidity from the memory, and compensate for the detection value based on the extracted compensation value.

The compensation value may be a compensation value of the signal output from the article detection sensor according to the humidity.

The compensation value may ensure that a capacitance value of the cavity detected by the article detection sensor remains lower than the reference value while the aerosol generating article is not inserted into the cavity.

The compensation value may be a compensation value of the reference value output from the article detection sensor according to the humidity.

The article detection sensor may include a capacitive sensor including at least one electrode, and the temperature sensor may be thin-film temperature sensor, and attached to the at least one electrode.

The temperature sensor may include a base attached to the at least one electrode, a first electrode formed on the base, a thermistor layer formed over the first electrode, and the base, and a second electrode formed over the thermistor layer and the base.

The article detection sensor may include a capacitive sensor including at least one electrode, and the humidity sensor may be thin-film humidity sensor, and attached to the at least one electrode.

The humidity sensor may include a base attached to the at least one electrode, a first electrode formed on the base, a moisture-sensitive layer formed on the first electrode, and a second electrode formed on the moisture-sensitive layer.

The signal may include at least one of a voltage change signal, a frequency change signal, or a change signal of a charge/discharge time.

The control unit may be configured to set a preheating temperature profile for the heater based on the signal output from the article detection sensor, and supply power to the heater according to the set preheating temperature profile.

### BRIEF DESCRIPTION OF THE DRAWINGS

The above and other aspects, features, and advantages of certain embodiments will be more apparent from the following description taken in conjunction with the accompanying drawings, in which:

FIG. 1 is a diagram illustrating an aerosol generating device according to an embodiment;

FIG. 2 is a diagram illustrating an aerosol generating device according to another embodiment;

FIG. 3 is a front perspective view of an aerosol generating device according to embodiments;

FIG. 4 is a cross-sectional diagram illustrating a combination of an upper case and a body of an aerosol generating device according to an embodiment;

FIG. 5 is a diagram illustrating a sensor according to an embodiment;

FIG. 6 is a cross-sectional diagram illustrating a thin-film temperature sensor according to an embodiment;

FIG. 7 is a cross-sectional diagram illustrating a thin-film temperature sensor according to an embodiment;

FIG. 8 is a perspective diagram illustrating a thin-film humidity sensor according to an embodiment;

FIG. 9 is a block diagram of an aerosol generating device according to an embodiment; and

FIG. 10 is a block diagram of an aerosol generating device according to another embodiment.

### DETAILED DESCRIPTION

With respect to the terms used to describe in the various embodiments, the general terms which are currently and widely used are selected in consideration of functions of structural elements in the various embodiments of the present disclosure. However, meanings of the terms can be changed according to intention, a judicial precedence, the appearance of a new technology, and the like. In addition, in certain cases, a term which is not commonly used can be selected. In such a case, the meaning of the term will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and changes such as “comprises” or “comprising” will be understood to imply the inclusion of stated elements but not the exclusion of any other elements. In addition, the terms “-er”, “-or”, and “module” described in the specification mean units for processing at least one function and operation and can be implemented by hardware components or software components and combinations thereof.

As used herein, when an expression such as “at least any one” precedes arranged elements, it modifies all elements rather than each arranged element. For example, the expression “at least any one of a, b, and c” should be construed to include a, b, c, or a and b, a and c, b and c, or a, b, and c.

In an embodiment, an aerosol generating device may be a device that generates aerosols by electrically heating a cigarette accommodated in an interior space thereof.

The aerosol generating device may include a heater. In an embodiment, the heater may be an electro-resistive heater. For example, the heater may include an electrically conductive track, and the heater may be heated when currents flow through the electrically conductive track.

The heater may include a tube-shaped heating element, a plate-shaped heating element, a needle-shaped heating element, or a rod-shaped heating element, and may heat the inside or outside of a cigarette according to the shape of a heating element.

A cigarette may include a tobacco rod and a filter rod. The tobacco rod may be formed of sheets, strands, and tiny bits cut from a tobacco sheet. Also, the tobacco rod may be surrounded by a heat conductive material. For example, the heat conductive material may be, but is not limited to, a metal foil such as aluminum foil.

The filter rod may include a cellulose acetate filter. The filter rod may include at least one segment. For example, the filter rod may include a first segment configured to cool aerosols, and a second segment configured to filter a certain component in aerosols.

In another embodiment, the aerosol generating device may be a device that generates aerosols by using a cartridge containing an aerosol generating material.

The aerosol generating device may include a cartridge that contains an aerosol generating material, and a main body that supports the cartridge. The cartridge may be detachably coupled to the main body, but is not limited thereto. The cartridge may be integrally formed or assembled with the main body, and may also be fixed to the main body so as not to be detached from the main body by a user. The cartridge may be mounted on the main body while accommodating an aerosol generating material therein. However, the disclosure is not limited thereto. An aerosol generating material may also be injected into the cartridge while the cartridge is coupled to the main body.

The cartridge may contain an aerosol generating material in any one of various states, such as a liquid state, a solid state, a gaseous state, a gel state, or the like. The aerosol generating material may include a liquid composition. For example, the liquid composition may be a liquid including a tobacco-containing material having a volatile tobacco flavor component, or a liquid including a non-tobacco material.

The cartridge may be operated by an electrical signal or a wireless signal transmitted from the main body to perform a function of generating aerosols by converting the phase of an aerosol generating material inside the cartridge into a gaseous phase. The aerosols may refer to a gas in which vaporized particles generated from an aerosol generating material are mixed with air.

In another embodiment, the aerosol generating device may generate aerosols by heating a liquid composition, and the generated aerosols may be delivered to a user through a cigarette. That is, the aerosols generated from the liquid composition may move along an airflow passage of the aerosol generating device, and the airflow passage may be configured to allow aerosols to be delivered to a user by passing through a cigarette.

In another embodiment, the aerosol generating device may be a device that generates aerosols from an aerosol generating material by using an ultrasonic vibration method. In this case, the ultrasonic vibration method may refer to a method of generating an aerosol by atomizing an aerosol generating material by using ultrasonic vibration generated by a vibrator.

The aerosol generating device may include a vibrator, and the vibrator may generate a short period of vibration to atomize the aerosol generating material. The vibration generated by the vibrator may be an ultrasound vibration, and the frequency band of the ultrasound vibration may be about 100 kHz to about 3.5 MHz, but is not limited thereto.

The aerosol generating device may further include a wick that absorbs the aerosol generating material. For example, the wick may be arranged to wrap at least one area of the vibrator or to be in contact with at least one area of the vibrator.

As the voltage (e.g., AC voltage) is applied to the vibrator, heat and/or ultrasonic vibration may be generated from the vibrator, and the heat and/or ultrasonic vibration generated from the vibrator may be transmitted to the aerosol generating material absorbed into the wick. The aerosol generating material absorbed into the wick may be converted to a gas phase by heat and/or ultrasonic vibration transmitted from the vibrator, and as a result, aerosol may be generated.

For example, the viscosity of the aerosol generating material absorbed into the wick by the heat generated from the vibrator may be lowered, and the aerosol generating material of which the viscosity is lowered by the ultrasonic vibration generated from the vibrator may be divided into fine particles, thereby generating aerosol, but embodiments are not limited thereto.

In another embodiment, the aerosol generating device is a device that generates aerosols by heating an aerosol generating article accommodated in the aerosol generating device in an induction heating method.

The aerosol generating device may include a susceptor and a coil. In an embodiment, the coil may apply a magnetic field to the susceptor. As power is supplied to the coil from the aerosol generating device, a magnetic field may be formed inside the coil. In an embodiment, the susceptor may be a magnetic body that generates heat by an external magnetic field. As the susceptor is positioned inside the coil and a magnetic field is applied to the susceptor, the susceptor generates heat to heat an aerosol generating article. In addition, optionally, the susceptor may be positioned within the aerosol generating article.

In another embodiment, the aerosol generating device may further include a cradle.

The aerosol generating device may configure a system together with a separate cradle. For example, the cradle may charge a battery of the aerosol generating device. Alternatively, the heater may be heated when the cradle and the aerosol generating device are coupled to each other.

Hereinafter, the present disclosure will now be described more fully with reference to the accompanying drawings, in which exemplary embodiments of the present disclosure are shown such that one of ordinary skill in the art may easily work the present disclosure. The disclosure may, however, be embodied in many different forms and should not be construed as being limited to the embodiments set forth herein.

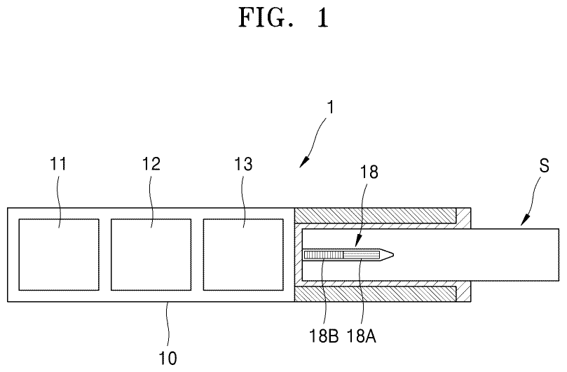

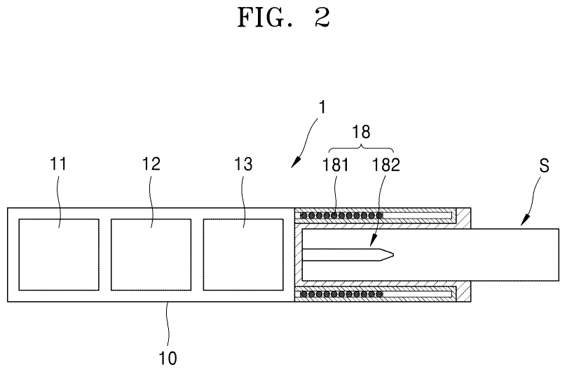

FIG. 1 is a diagram illustrating an aerosol generating device according to an embodiment of the disclosure, and FIG. 2 is a diagram illustrating an aerosol generating device according to another embodiment.

Referring to FIGS. 1 to 2, an aerosol generating device 1 according to embodiments may include at least one of a battery 11, a control unit 12, a sensor unit 13, or a heater 18. At least one of the battery 11, the control unit 12, the sensor unit 13, or the heater 18 may be disposed inside a body 10 of the aerosol generating device 1. The body 10 may provide a space opened upward such that an aerosol generating article S is inserted. The space opened upward may be referred to as an insertion space or cavity. The cavity may be formed by being recessed toward the inside of the body 10 by a certain depth such that at least a part of the aerosol generating article S may be inserted. The depth of the cavity may correspond to the length of a region including an aerosol generating material and/or a medium in the aerosol generating article S. The lower end of the aerosol generating article S may be inserted into the body 10, and the upper end of the aerosol generating article S may protrude to the outside of the body 10. A user may inhale air with the upper end of the aerosol generating article S exposed to the outside in a user's mouth. According to an embodiment, the aerosol generating device 1 may further include a vaporizer (not shown), and an aerosol generated by the vaporizer may pass through the aerosol generating article S and be delivered to the user. To this end, the vaporizer may include a liquid storage unit, a liquid transfer means, and an additional heating element.

The heater 18 may heat the aerosol generating article S. The heater 18 may extend long upward in a space into which the aerosol generating article S is inserted. For example, the heater 18 may include a tubular-shaped heating element, a plate-shaped heating element, a needle-shaped heating element, or a rod-shaped heating element. The heater 18 may be inserted into the lower portion of the aerosol generating article S. According to the embodiment, the heater 18 may include a cylindrical heating element unlike FIGS. 1 and 2, and the cylindrical heating element may accommodate the aerosol generating article S to heat at least a part of the outer surface of the aerosol generating article S.

The heater 18 may include an electrically resistive heater and/or an induction heating-type heater.

For example, referring to FIG. 1, the heater 18 may be a resistive heater. For example, the heater 18 may include an electrically conductive track, and the heater 18 may be heated when a current flows through the electrically conductive track. The heater 18 may be electrically connected to the battery 11. The heater 18 may receive a current from the battery 11 and directly generate heat. The heater 18 may be referred to as a heating unit in that it is configured to heat the aerosol generating article S.

For example, the heater 18 may be a multi-heater. The heater 18 may include a first heater 18A and a second heater 18B. The first heater 18A and the second heaters 18B may be disposed side by side in a longitudinal direction. The first heater 18A and the second heaters 18B may be heated sequentially or simultaneously.

For example, referring to FIG. 2, the aerosol generating device 1 may include an induction coil 181 surrounding a susceptor 182. The induction coil 181 may heat the susceptor 182. In an example in which the heater 18 of the aerosol generating device 1 is an induction heating type heater, the induction coil 181 and the susceptor 182 may be referred to as the heater 18. In an embodiment, only the susceptor 182 may be referred to as the heater 18. In addition, the induction coil 181 and the susceptor 182 may be referred to as a heating unit in that the induction coil 181 and the susceptor 182 contribute to heating.

The susceptor 182 may generate heat by a magnetic field generated by an AC current flowing through the induction coil 181. The magnetic field may penetrate the susceptor 182 and generate an eddy current in the susceptor 182. The current may generate heat in the susceptor 182. As shown in FIG. 2, the susceptor 182 may be a tubular-shaped heating element, a plate-shaped heating element, a needle-shaped heating element, or a rod-shaped heating element, but according to the embodiment, the susceptor 182 may be in a cylindrical shape to accommodate the aerosol generating article S and heat at least a part of the outer surface of the aerosol generating article S. In addition, according to the embodiment, the susceptor 182 may be included in the aerosol generating article S rather than the aerosol generating device 1.

The battery 11 may supply power for the components of the aerosol generating device 1 to operate. The battery 11 may supply power to at least one of the control unit 12, the sensor unit 13, or the heater 18.

The controller 12 may control overall operations of the aerosol generating device 1. The control unit 12 may be mounted on a printed circuit board (PCB). The control unit 12 may control an operation of at least one of the battery 11, the sensor unit 13, or the heater 18. The control unit 12 may control the operation of the induction coil 181. The control unit 12 may control operations of a display, a motor, etc. installed in the aerosol generating device 1. The control unit 12 may identify the states of each of the components of the aerosol generating device 1 to determine whether the aerosol generating device 1 is operable.

The control unit 12 may analyze a result detected by the sensor unit 13 and control processes to be subsequently performed. For example, the control unit 12 may control the power supplied to the heater 18 such that the operation of the heater 18 starts or ends based on the result detected by the sensor unit 13. For example, the control unit 12 may control the amount of power supplied to the heater 18 and the time when the power is supplied such that the heater 18 may be heated to a certain temperature or maintained at an appropriate temperature, based on the result detected by the sensor unit 13.

The sensor unit 13 may include at least one of a humidity sensor, a temperature sensor, a puff sensor, an insertion detection sensor, or an acceleration sensor. For example, the sensor unit 13 may sense at least one of the temperature of the heater 18, the temperature of the battery 11, or the temperature inside and outside the body 10. For example, the sensor unit 13 may sense a user's puff. For example, the sensor unit 13 may sense whether the aerosol generating article S is inserted into the cavity. For example, the sensor unit 13 may sense the movement of the aerosol generating device 1.

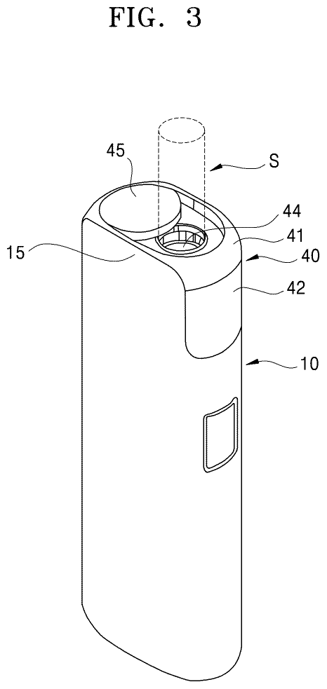

FIG. 3 is a front perspective view of an aerosol generating device according to embodiments.

Hereinafter, a case where the heater 18 is an induction heating type heater is mainly described in FIG. 3, but the following description may also be applied to the electrical resistive heater of FIG. 1.

Referring to FIG. 3, an upper case 40 may be detachably coupled to the body 10. The upper case 40 may be coupled to the upper side of the body 10. The upper case 40 may cover the upper periphery of the body 10. The upper case 40 may include an insertion hole 44. The aerosol generating article S may be inserted into the insertion hole 44. The insertion hole 44 may be a configuration corresponding to the insertion space or cavity described with reference to FIGS. 1 and 2. The upper case 40 may include a cover 45 opening and closing the insertion hole 44. The cover 45 may slide in a transverse direction to open and close the insertion hole 44.

The upper case 40 may include an upper case wing 42. The upper case wing 42 may extend downward from both sides of the upper case body 41. The upper case wing 42 may be referred to as an upper case grip 42.

The body 10 may include body wings 15. The body wings 15 may extend upward from the upper edge of the body 10. The body wings 15 may be formed as a pair facing each other with respect to the upper portion of the body 10. The body wings 15 may be formed at positions deviated from the upper case wing 42.

When the upper case 40 is coupled to the body 10, the upper case 40 may form the upper appearance of an aerosol generating device. When the upper case 40 is coupled to the body 10, the body wings 15 may cover side portions of the upper case 40 exposed between the upper case wing 42. When the upper case 40 is coupled to the body 10, the upper case wing 42 may cover the outer wall of the body 10.

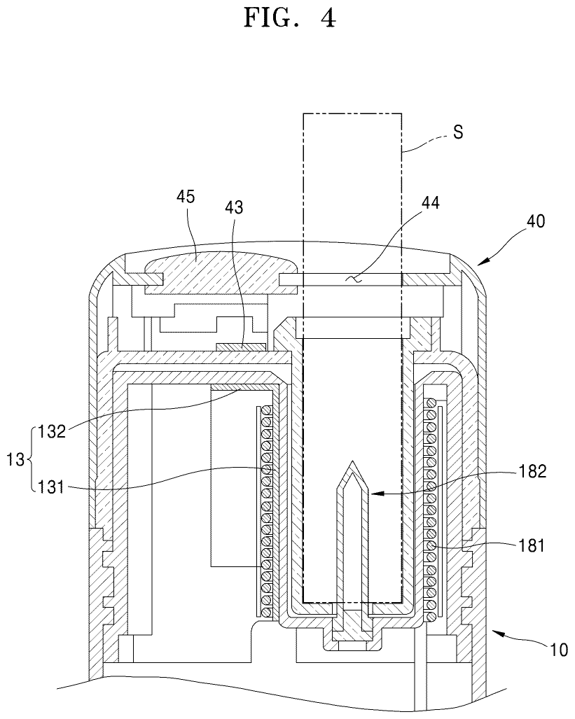

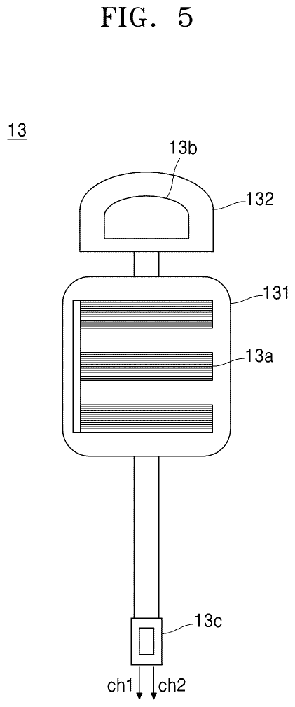

FIG. 4 is a cross-sectional diagram illustrating a combination of an upper case and a body of an aerosol generating device according to an embodiment. FIG. 5 is a diagram illustrating a sensor according to an embodiment.

Referring to FIGS. 4 to 5, the upper case 40 may be detachably coupled to the body 10. The upper case 40 may include the insertion hole 44. The cover 45 may be movably installed in the upper case 40 to open or close the insertion hole 44.

When the insertion hole 44 is opened, the aerosol generating article S may be accommodated in the aerosol generating device 1 through the insertion hole 44. The susceptor 182 may be fixed to the body 10 or according to an embodiment may be interchangeably coupled to the body 10. When the aerosol generating article S is accommodated in the aerosol generating device 1 through the insertion hole 44, the susceptor 182 may be inserted into the aerosol generating article S.

The induction coil 181 may surround the outer circumferential surface of a cavity forming the insertion hole 44, and generate a variable magnetic field by using AC power. The variable magnetic field may be provided to the susceptor 182, and the susceptor 182 may be inductively heated by the variable magnetic field.

The sensor unit 13 may include an article detection sensor 131 and an upper case detection sensor 132. The article detection sensor 131 and the upper case detection sensor 132 may be integrally formed.

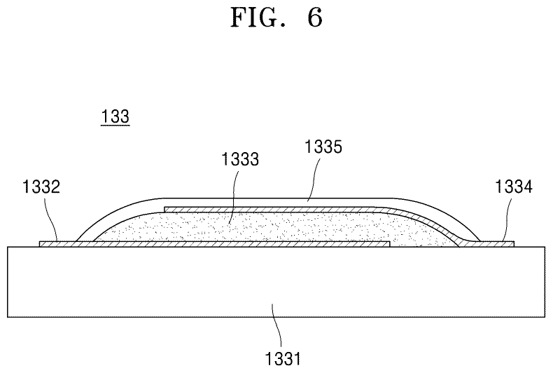

In an embodiment, the sensor unit 13 may further include at least one of a temperature sensor (not shown) or a humidity sensor (not shown). The temperature sensor or the humidity sensor may be configured as a thin film. At least one of the temperature sensor or the humidity sensor may be configured as a thin film and attached to the article detection sensor 131 to be integrally formed. Detailed descriptions of the temperature sensor and the humidity sensor will be given below with reference to FIGS. 6 to 8.

The article detection sensor 131 may be disposed between the outer circumferential surface of the cavity and the induction coil 181 to detect whether the aerosol generating article S inserted into the cavity through the insertion hole 44 is present. The article detection sensor 131 may be manufactured as a thin film so as to be disposed between the cavity and the induction coil 181. The article detection sensor 131 may surround at least a part of the outer circumferential surface of the cavity, and an output signal value may vary according to the magnitude of capacitance of the cavity. In addition, the article detection sensor 131 may transmit the output signal value to the control unit 12.

The upper case detection sensor 132 may be connected to the article detection sensor 131 to be integrally formed. The upper case detection sensor 132 may be disposed inside a surface in which the upper case 40 is in contact with the body 10 and may extend in one direction. One direction may be perpendicular to an insertion direction of the aerosol generating article S. The upper case 40 may include at least one conductor 43 in a part in contact with the upper case detection sensor 132, and the upper case detection sensor 132 may output an output value that varies according to the approach and retreat of the at least one conductor 43. The upper case detection sensor 132 may transmit the output value to the control unit 12.

The upper case detection sensor 132 and the article detection sensor 131 may be integrally formed. The upper case detection sensor 132 and the article detection sensor 131 may be implemented in a pattern shape on a base. The base may include an insulator through which no current passes. For example, the upper case detection sensor 132 and the article detection sensor 131 may be implemented in a pattern shape on one flexible printed circuit board (FPCB).

The upper case detection sensor 132 may include an interactive sensor. In an embodiment in which the upper case detection sensor 132 includes the interactive sensor, the upper case detection sensor 132 may include a detection coil 13b. The sensing coil 13b may be implemented in a pattern shape on the base. The article detection sensor 131 may have inductance that varies according to the approach and retreat of the upper case 40, and may transmit a varied inductance value to the control unit 12. To this end, the sensor unit 13 may further include a signal transmission unit 13c. The signal transmission unit 13c may include a first channel ch1 and a second channel ch2, and the signal transmission unit 13c may transmit the varied inductance value to the control unit 12 through the first channel ch1.

The article detection sensor 131 may include at least one capacitor sensor. In an embodiment in which the article detection sensor 131 includes a capacitor sensor, the article detection sensor 131 may include at least one electrode 13a. FIG. 5 illustrates an embodiment with three electrodes 13a, but the number of electrodes 13a is not limited thereto. The electrodes 13a may be implemented in a pattern shape on the base. The electrodes 13a may contact the outer circumferential surface of the cavity and surround at least a part of the outer circumferential surface of the cavity. According to the embodiment, the sensor unit 13 may be externally coated, and an external coating layer may directly contact the outer peripheral surface of the cavity.

The electrodes 13a surround the cavity, and thus the cavity may be understood as a dielectric space causing a change in capacitance. In other words, when the aerosol generating article S is inserted into the cavity, the dielectric constant of the electrode 13a may vary, and the capacitance of the article detection sensor 131 may vary. As described above, the article detection sensor 131 does not separately include a transmission electrode and a reception electrode, but may output a signal that varies according to a change in the capacitance of the electrodes 13a itself. In the disclosure, a ‘signal’ is a signal corresponding to a change in capacitance in a cavity, and may refer to a voltage change signal, a frequency change signal, or a change signal of charging/discharging time. The controller 12 (see FIG. 1) may obtain a signal output from the article detection sensor 131. The signal transmission unit 13c may transmit the signal to the control unit 12 (see FIG. 1) through the second channel ch2 different from the first channel ch1.

In an embodiment, at least one of a temperature sensor or a humidity sensor may be configured as a thin film and attached to the article detection sensor 131 to be integrally formed. Specifically, at least one of the temperature sensor or the humidity sensor may be configured as a thin film and attached to an electrode constituting capacitance to be integrally formed. The temperature sensor may sense the ambient temperature of the article detection sensor 131. The humidity sensor may sense the ambient humidity of the article detection sensor 131. Detailed descriptions of the temperature sensor and the humidity sensor configured as the thin film are given below with reference to FIGS. 6 to 8.

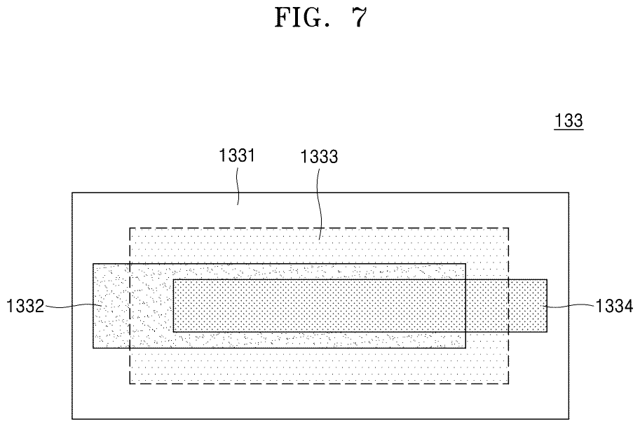

FIG. 6 is a cross-sectional diagram illustrating a thin-film temperature sensor according to an embodiment. FIG. 7 is a cross-sectional diagram illustrating a thin-film temperature sensor according to an embodiment.

Referring to FIGS. 6 to 7, a temperature sensor 133 may be configured as a thin film. The thin-film temperature sensor 133 may include a base 1331, a first electrode 1332, a second electrode 1334, and a thermistor layer 1333, and may optionally include a protective layer 1335.

An insulating alumina (Al₂O₃) substrate may be applied to the base 1331. In an embodiment, the temperature sensor 133 and the article detection sensor 131 (FIG. 5) may be integrally formed using a base commonly. That is, the temperature sensor 133 may be attached to the electrode 13a (FIG. 5) constituting the article detection sensor 131 (FIG. 5) by using the base and the article detection sensor 131 (FIG. 5) commonly.

The thermistor layer 1333 may include a thermal resistance material, a piezoresistive material, or a mixture thereof. Electrical characteristics of the thermistor layer 1333 may be changed according to temperature. Specifically, resistance characteristics of the thermistor layer 1333 may be changed according to temperature.

The temperature sensor 133 includes the base 1331, the first electrode 1332 formed on the base 1331, the thermistor layer 1333 formed over the first electrode 1332 and the base 1331, and the second electrode 1334 formed over the thermistor layer 1333 and the base 1331. The thermistor layer 1333 is formed to have a width such that the first electrode 1332 is included therein and is in contact with the base 1331 in the remaining portion excluding the first electrode 1332. The first electrode 1332 and the second electrode 1334 may be formed through a firing process after printing a paste including palladium (Pd) and platinum (pt), and the thermistor layer 1333 may be formed by printing a slurry mixed with ceramic powder and then firing the slurry.

The protective layer 1335 is an electrical insulating material, formed on the entire surface between the first electrode 1332 and the second electrode 1334 except for a part of each of the first electrode 1332 and the second electrode 1334, and a film including a glass or polymer material that withstands high temperature may be formed by a printing process.

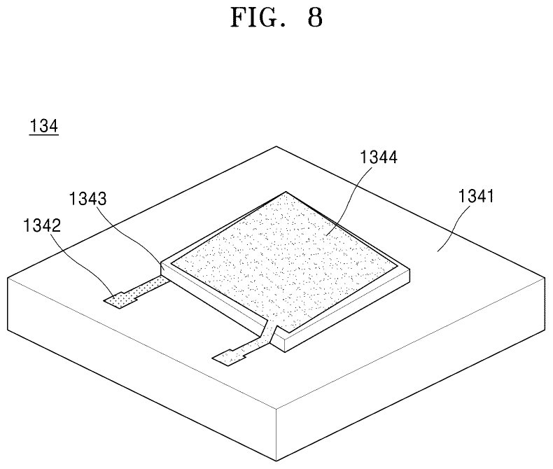

FIG. 8 is a perspective diagram illustrating a thin-film humidity sensor according to an embodiment.

A humidity sensor 134 may be configured as a thin film. The humidity sensor 134 includes a base 1341, a first electrode 1342 formed on the base 1341, a moisture-sensitive layer 1343 formed on the first electrode 1342, and a second electrode 1344 formed on the moisture-sensitive layer 1343.

The moisture-sensitive layer 1343 may include a polymer material, and electrical characteristics thereof may be changed according to the adsorption and desorption of moisture by applying a moisture-sensitive film structure. Specifically, when moisture is adsorbed into the moisture-sensitive layer 1343, a resistance component between the first electrode 1342 and the second electrode 1344 may be changed and detected so that a change in humidity may be detected.

In an embodiment, an insulating alumina (Al₂O₃) substrate may be applied to the base 1341. In an embodiment, the humidity sensor 134 and the article detection sensor 131 (FIG. 5) may be integrally formed using a base commonly. That is, the humidity sensor 134 may be attached to the electrode 13a (FIG. 5) constituting the article detection sensor 131 (FIG. 5) by using the base and the article detection sensor 131 (FIG. 5) commonly.

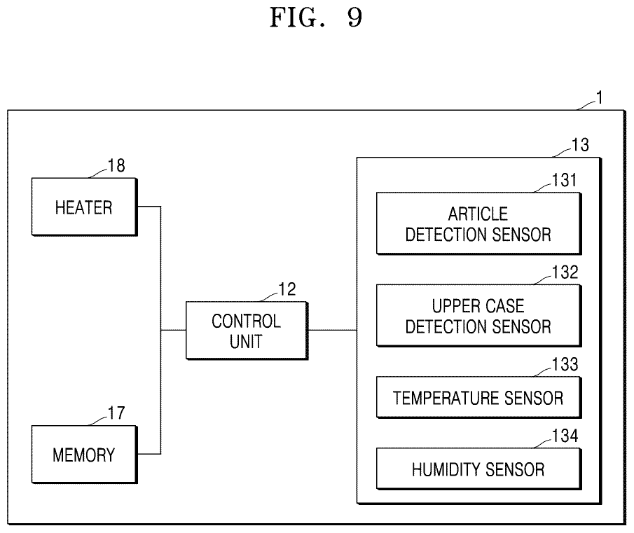

FIG. 9 is a block diagram of an aerosol generating device according to an embodiment.

Referring to FIGS. 1 to 9, the aerosol generating device 1 according to an embodiment includes the control unit 12, the heater 18, a memory 17, and the sensor unit 13. However, the internal structure of the aerosol generating device 1 is not limited to that shown in FIG. 9. That is, it may be understood by one of ordinary skill in the technical field related to the present embodiment that some of the components shown in FIG. 9 may be omitted or new components may be further added according to the design of the aerosol generating device 1.

The heater 18 may heat at least a part of the aerosol generating article S inserted into a cavity.

The sensor unit 13 may include the article detection sensor 131, the upper case detection sensor 132, the temperature sensor 133, and the humidity sensor 134. As described above, at least one of the temperature sensor 133 or the humidity sensor 134 may be configured as a thin film and attached to the article detection sensor 131 and an electrode constituting capacitance to be integrally formed.

The temperature sensor 133 may be integrally formed with the article detection sensor 131 to detect the ambient temperature of the article detection sensor 131.

The humidity sensor 134 may be integrally formed with the article detection sensor 131 to detect the ambient humidity of the article detection sensor 131.

The article detection sensor 131 may output a signal by detecting a change in the capacitance of a cavity. The change in the capacitance detected by the article detection sensor 131 may be affected by temperature and humidity. That is, even when there is no change in the capacitance of the cavity, a signal output by the article detection sensor 131 may vary according to a change in temperature or humidity. Therefore, in the disclosure, a change characteristic of a signal value output by the article detection sensor 131 that changes according to temperature and humidity is identified, and a compensation value is determined according to the identified change characteristic. In addition, a lookup table for the determined compensation value may be previously stored in the memory 17.

The lookup table may include a first lookup table including a compensation value according to temperature, a second lookup table including a compensation value according to humidity, and a third lookup table including a compensation value according to temperature and humidity. In this regard, the article detection sensor 131 is affected by both temperature and humidity, and thus the signal value may be compensated for in consideration of both temperature and humidity.

The control unit 12 may be electrically connected to the sensor unit 13, the heater 18, and the memory 17.

The control unit 12 may determine whether the upper case 40 is mounted on the body 10 based on an inductance value output from the upper case detection sensor 132. For example, when the amount of change per unit time of inductance output by the upper case detection sensor 132 is greater than or equal to a preset reference inductance, the control unit 12 may determine that the upper case 40 is mounted on the body 10.

The control unit 12 may determine whether the aerosol generating article S is inserted based on a signal output from the article detection sensor 131. For example, the control unit 12 may obtain a signal from the article detection sensor 131 and compare the signal with a preset reference value to generate a detection value, and when the generated detection value is within a preset range, determine that the aerosol generating article S has been inserted into the cavity.

The control unit 12 may set a preheating temperature profile for the heater 18 based on the signal output from the article detection sensor 131, and supply power to the heater 18 according to the set preheating temperature profile. The control unit 12 may analyze a result detected by the article detection sensor 131 and control processes to be subsequently performed. For example, the control unit 12 may control the power supplied to the heater 18 such that the operation of the heater 18 starts or ends based on the result detected by the article detection sensor 131. For another example, the control unit 12 may control the amount of power supplied to the heater 18 and the time when the power is supplied such that the heater 18 may be heated to a certain temperature or maintained at an appropriate temperature based on the result detected by the article detection sensor 131.

A compensation value for compensating for the detected value may be previously stored in the memory 17. A compensation value for compensating for the detection value according to temperature and humidity is previously determined through an experiment, and a lookup table is prepared accordingly and stored in the memory 17. In order to ensure the reliability of an operation of detecting the insertion of the aerosol generating article S, the compensation value may ensure that a capacitance value of the cavity detected by the article detection sensor 131 remains lower than the reference value while the aerosol generating article S is not inserted into the cavity.

The lookup table may include a compensation value corresponding to temperature/humidity. For example, the lookup table may include a first compensation value applied under conditions of A temperature and B humidity, a second compensation value applied under conditions of A temperature and C humidity, a third compensation value applied under conditions of D temperature and B humidity, and a fourth compensation value applied under conditions of D temperature and C humidity. That is, the lookup table may not include a compensation value for any one of temperature and humidity conditions, but may include a compensation value considering both temperature and humidity.

The control unit 12 may obtain the ambient temperature of the article detection sensor 131 from the temperature sensor 133, when a signal output from the article detection sensor 131 is obtained, identify the temperature at the time when the signal is obtained, extract a compensation value corresponding to the temperature from the memory 17, and compensate for a detection value based on the extracted compensation value.

The control unit 12 may calculate the detection value as a value obtained by subtracting the reference value from the signal output by the article detection sensor 131. When the detection value is a minus value, the control unit 12 may determine the signal output from the article detection sensor 131 as noise.

For example, when a reference temperature is set to 25 degrees and the reference value is set to a signal value corresponding to capacitance “100 pF”, the signal value generated by the article detection sensor 131 is a signal value corresponding to capacitance “300 pF”. At this time, when temperature data at the time the signal value is obtained is 25 degrees, a signal value corresponding to capacitance of “200 pF”, which is a difference between the reference value and the signal value generated by the article detection sensor 131, is generated as the detection value. When the detection value is included within a preset range, the control unit 12 determines that the aerosol generating article S is inserted into the cavity. The preset range may be, for example, a positive (+) value greater than 0. On the other hand, when the temperature data at the time when the signal output from the article detection sensor 131 is obtained is 30 degrees, the control unit 12 identifies a compensation value corresponding to the temperature data by using a compensation table stored in the memory 17. In this regard, the compensation value may be a value applied to the reference value, or may be a value applied to the signal value obtained through the article detection sensor 131. When the compensation value is the value applied to the reference value and the compensation value corresponding to the temperature data is a signal value corresponding to capacitance “250 pF”, the control unit 12 may change the reference value from the signal value corresponding to capacitance “100 pF” to a signal value corresponding to capacitance “350 pF”. At this time, the signal value generated by the article detection sensor 131 is a signal value corresponding to the capacitance “300 pF”, which is lower than the compensated reference value, and thus the control unit 12 may determine the signal output by the article detection sensor 131 as noise and ignore the signal value.

In addition, when the compensation value is applied to the signal value output from the article detection sensor 131 and the compensation value corresponding to the temperature data is a signal value corresponding to the capacitance “250 pF”, the control unit 12 may change the signal value obtained through the article detection sensor 131 from the signal value corresponding to the capacitance “300 pF” to the signal value corresponding to capacitance “50 pF”. At this time, the signal value generated by the article detection sensor 131 is a signal value corresponding to the capacitance “50 pF”, and the reference value is lower than the signal value corresponding to the capacitance “100 pF”, and thus the control unit 12 may determine the signal output by the article detection sensor 131 as noise and ignore the signal value.

The control unit 12 may obtain the ambient humidity of the article detection sensor 131 from the humidity sensor 134, and when a signal output from the article detection sensor 131 is obtained, identify the humidity at the time when the signal is obtained, extract a compensation value corresponding to the humidity from the memory 17, and compensate for the detection value based on the extracted compensation value.

The control unit 12 may calculate the detection value as a value obtained by subtracting the reference value from the signal output by the article detection sensor 131. When the detection value is a minus value, the control unit 12 may determine the signal output from the article detection sensor 131 as noise.

For example, when a reference humidity is set to 40% and the reference value is accordingly set to the signal value corresponding to the capacitance “100 pF”, the signal value generated by the article detection sensor 131 is the signal value corresponding to the capacitance “300 pF”. At this time, when humidity data at the time the signal value is obtained is 40%, a signal value corresponding to the capacitance of “200 pF”, which is a difference between the reference value and the signal value generated by the article detection sensor 131, is generated as the detection value. When the detection value is included within a preset range, the control unit 12 determines that the aerosol generating article S is inserted into the cavity. The preset range may be, for example, a positive (+) value greater than 0. On the other hand, when the humidity data at the time when the signal output from the article detection sensor 131 is obtained is 60%, the control unit 12 identifies a compensation value corresponding to the humidity data by using a compensation table stored in the memory 17. In this regard, the compensation value may be a value applied to the reference value, or may be a value applied to the signal value obtained through the article detection sensor 131. When the compensation value is the value applied to the reference value and the compensation value corresponding to the humidity data is a signal value corresponding to capacitance “220 pF”, the control unit 12 may change the reference value from the signal value corresponding to the capacitance “100 pF” to a signal value corresponding to capacitance “320 pF”. At this time, the signal value generated by the article detection sensor 131 is a signal value corresponding to the capacitance “300 pF”, which is lower than the reference value, and thus the control unit 12 may determine the signal output by the article detection sensor 131 as noise and ignore the signal value.

In addition, when the compensation value is applied to the signal value output from the article detection sensor 131 and the compensation value corresponding to the temperature data is the signal value corresponding to the capacitance “220 pF”, the control unit 12 may change the signal value obtained through the article detection sensor 131 from the signal value corresponding to the capacitance “300 pF” to a signal value corresponding to capacitance “80 pF”. At this time, the signal value generated by the article detection sensor 131 is the signal value corresponding to the capacitance “80 pF”, and the reference value is lower than the signal value corresponding to the capacitance “100 pF”, and thus the control unit 12 may determine the signal output by the article detection sensor 131 as noise and ignore the signal value.

When the detected value or the compensated detection value is beyond the preset range, the control unit 12 may recognize it as a detection value generated by the aerosol generating article S that is not genuine or a foreign substance. That is, when the detection value or the compensated detection value beyond the preset range, the control unit 12 may determine that the aerosol generating article S inserted into the cavity is not genuine. In addition, when the detection value or the compensated detection value is beyond the preset range, the control unit 12 may determine that a foreign substance has been inserted into the cavity.

In the disclosure, a compensation algorithm according to temperature is applied in a normal state to flexibly change the reference value or the signal value output by the article detection sensor 131, and thus there is a certain difference value between the reference value and the signal value accordingly. That is, the signal value output by the article detection sensor 131 in the normal state has a value lower than the reference value. Accordingly, only when the signal value has a value greater than the reference value, the control unit 12 may determine whether the aerosol generating article S is inserted based on the signal output from the article detection sensor 131.

Here, the normal state is a test environment of the article detection sensor 131 for setting the reference value, and, for example, refers to a state in which the aerosol generating article S and a foreign substance are not inserted into the cavity in a temperature environment of 25° C. and a humidity environment of 50%.

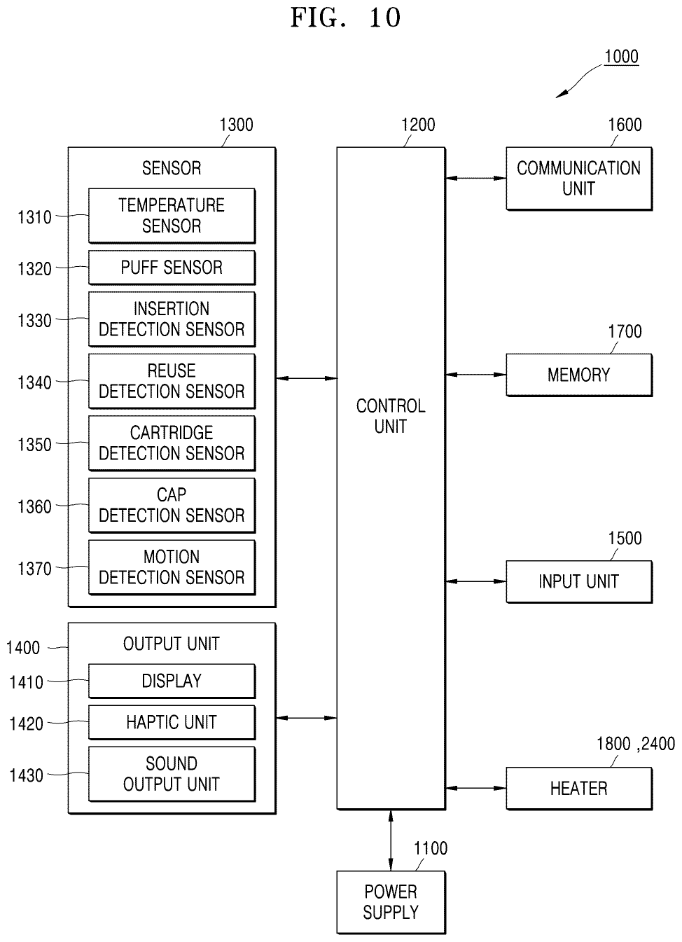

FIG. 10 is a block diagram of an aerosol generating device according to another embodiment.

An aerosol generating device 1000 may include a power supply 1100, a control unit 1200, a sensor 1300, an output unit 1400, an input unit 1500, a communication unit 1600, a memory 1700, and one or more heaters 1800 and 2400. However, an internal structure of the aerosol generating device 1000 is not limited to that shown in FIG. 10. In other words, according to the design of the aerosol generating device 1000, one of ordinary skill in the art related to the present embodiment that some of the components shown in FIG. 10 may be omitted or new components may be added

The sensor 1300 may detect a state of the aerosol generating device 1000 or a state around the aerosol generating device 1000 and transmit detected information to the control unit 1200. Based on the detected information, the control unit 1200 may control the aerosol generating device 1000 to perform various functions such as control of operations of the cartridge heater 2400 and/or the heater 1800, a restriction on smoking, determination of whether an aerosol generating article and/or a cartridge 19 are inserted, and a notification display.

The sensor 1300 may include at least one of a temperature sensor 1310, a puff sensor 1320, an insertion detection sensor 1330, a reuse detection sensor 1340, a cartridge detection sensor 1350, a cap detection sensor 1360, or a motion detection sensor 1370.

The temperature sensor 1310 may detect a temperature at which the cartridge heater 2400 and/or the heater 1800 are heated. The aerosol generating device 1000 may include a separate temperature sensor detecting the temperatures of the cartridge heater 2400 and/or the heater 1800, or the cartridge heater 2400 and/or the heater 1800 may operate as temperature sensors.

The temperature sensor 1310 may output a signal corresponding to the temperature of the cartridge heater 2400 and/or the heater 1800. For example, the temperature sensor 1310 may include a resistor element whose resistance value changes in correspondence to a change in the temperature of the cartridge heater 2400 and/or the heater 1800. The temperature sensor 1310 may be implemented by a thermistor, which is an element using a property of changing resistance according to temperature. In this regard, the temperature sensor 1310 may output a signal corresponding to the resistance value of the resistor element as a signal corresponding to the temperature of the cartridge heater 2400 and/or the heater 1800. For example, the temperature sensor 1310 may include a sensor detecting a resistance value of the cartridge heater 2400 and/or the heater 1800. Here, the temperature sensor 1310 may output a signal corresponding to the resistance value of the cartridge heater 2400 and/or the heater 1800 as the signal corresponding to the temperature of the cartridge heater 2400 and/or the heater 1800.

The temperature sensor 1310 may be disposed around the power supply 1100 to monitor a temperature of the power supply 1100. The temperature sensor 1310 may be disposed adjacent to the power supply 1100. For example, the temperature sensor 1310 may be attached to one surface of a battery that is the power supply 1100. For example, the temperature sensor 1310 may be mounted on one surface of a printed circuit board (PCB).

The temperature sensor 1310 may be disposed inside an aerosol generating device main body to detect an internal temperature of the aerosol generating device main body.

The puff sensor 1320 may detect a user's puff based on various physical changes in an airflow path. The puff sensor 1320 may output a signal corresponding to the puff. For example, the puff sensor 1320 may include a pressure sensor. The puff sensor 1320 may output a signal corresponding to internal pressure of the aerosol generating device 1000. Here, the internal pressure of the aerosol generating device 1000 may correspond to the pressure of the airflow path through which a gas flows. The puff sensor 1320 may be disposed to correspond to the airflow path through which the gas flows in the aerosol generating device 1000.

The insertion detection sensor 1330 may detect insertion and/or removal of the aerosol generating article. The insertion detection sensor 1330 may detect a signal change due to the insertion and/or removal of the aerosol generating article. The insertion detection sensor 1330 may be installed around an insertion space. The insertion detection sensor 1330 may detect the insertion and/or removal of the aerosol generating article according to a change in a dielectric constant inside the insertion space. For example, the insertion detection sensor 1330 may be an inductive sensor and/or a capacitance sensor.

The inductive sensor may include at least one coil. The coil of the inductive sensor may be disposed adjacent to the insertion space. For example, when a magnetic field changes around the coil through which a current flows, characteristics of the current flowing through the coil may change according to Faraday's law of electromagnetic induction. Here, the characteristics of the current flowing through the coil may include a frequency of an alternating current, a current value, a voltage value, an inductance value, an impedance value, etc.

The inductive sensor may output a signal corresponding to the characteristics of the current flowing through the coil. For example, the inductive sensor may output a signal corresponding to an inductance value of the coil.

The capacitance sensor may include a conductor. The conductor of the capacitance sensor may be disposed adjacent to the insertion space. The capacitance sensor may output a signal corresponding to an ambient electromagnetic characteristic, e.g., a capacitance around the conductor. For example, when the aerosol generating article including a metal wrapper is inserted into the insertion space, the electromagnetic characteristic around the conductor may be changed by the wrapper of the aerosol generating article.

The reuse detection sensor 1340 may detect whether the aerosol generating article is reused. The reuse detection sensor 1340 may be a color sensor. The color sensor may detect a color of the aerosol generating article. The color sensor may detect a color of a part of the wrapper wrapping the outside of the aerosol generating article. The color sensor may detect a value with respect to an optical characteristic corresponding to a color of an object, based on light reflected from the object. For example, the optical characteristic may be a wavelength of light. The color sensor may be implemented as a single component with a proximity sensor or may be implemented as a separate component distinguished from the proximity sensor.

At least a part of the wrapper constituting the aerosol generating article may have a color changing by an aerosol. When the aerosol generating article is inserted into the insertion space, the reuse detection sensor 1340 may be disposed in correspondence to a location at which at least a part of the wrapper whose color changes by the aerosol is disposed. For example, before the aerosol generating article is used by a user, the color of at least a part of the wrapper may be a first color. In this regard, when at least a part of the wrapper is wetted by the aerosol while the aerosol generated by the aerosol generating device 1000 passes through the aerosol generating article, the color of at least a part of the wrapper may be changed to a second color. Meanwhile, the color of at least a part of the wrapper may be maintained in the second color after changing from the first color to the second color.

The cartridge detection sensor 1350 may detect mounting and/or removal of the cartridge 19. The cartridge detection sensor 1350 may be implemented by an inductance-based sensor, a capacitive sensor, a resistance sensor, a hall sensor (a hall IC) using a hall effect, etc.

The cap detection sensor 1360 may detect mounting and/or removal of a cap. When the cap is detached from the aerosol generating device main body, a part of the cartridge 19 and the aerosol generating device main body covered by the cap may be exposed to the outside. The cap detection sensor 1360 may be implemented by a contact sensor, a hall sensor (a hall IC), an optical sensor, etc.

The motion detection sensor 1370 may detect a motion of the aerosol generating device 1000. The motion detection sensor 1370 may be implemented as at least one of an acceleration sensor and a gyro sensor.

In addition to the temperature sensor 1310, the puff sensor 1320, the insertion detection sensor 1330, the reuse detection sensor 1340, the cartridge detection sensor 1350, the cap detection sensor 1360, and the motion detection sensor 1370 described above, the sensor 1300 may further include at least one of a humidity sensor, an atmospheric pressure sensor, a magnetic sensor, a global positioning system (GPS), or a proximity sensor. Functions of the respective sensors may be intuitively inferred from names thereof by one of ordinary skill in the art, and thus, detailed descriptions thereof may be omitted.

The output unit 1400 may output information about the state of the aerosol generating device 1000 and provide the information to the user. The output unit 1400 may include at least one of a display 1410, a haptic unit 1420, and a sound output unit 1430, but is not limited thereto. When the display 1410 and a touch pad form a layer structure to form a touch screen, the display 1410 may be used as an input device in addition to an output device.

The display 1410 may visually provide the user with information of the aerosol generating device 1000. For example, the information of the aerosol generating device 1000 may refer to various types of information such as a charging/discharging state of the power supply 1100 of the aerosol generating device 1000, a preheating state of the heater 1800, the insertion/removal state of the aerosol generating article and/or the cartridge 19, the mounting/removal state of the cap, and the restriction on use of the aerosol generating device 1000 (e.g., detection of an abnormal article), and the display 1410 may output the information to the outside. For example, the display 1410 may be in the form of a light emitting diode (LED) light emitting device. For example, the display 1410 may be a liquid crystal display (LCD) panel, an organic light emitting display (OLED) panel, etc.

The haptic unit 1420 may tactilely provide the user with the information of the aerosol generating device 1000 by converting an electrical signal into a mechanical stimulus or an electrical stimulus. For example, when initial power is supplied to the cartridge heater 2400 and/or the heater 1800 for a set time, the haptic unit 1420 may generate vibration corresponding to completion of initial preheating. The haptic unit 1420 may include a vibration motor, a piezoelectric element, or an electrical stimulation device.

The sound output unit 1430 may audibly provide the user with the information of the aerosol generating device 1000. For example, the sound output unit 1430 may convert the electrical signal into a sound signal and output the sound signal to the outside.

The power supply 1100 may supply power used to operate the aerosol generating device 1000. The power supply 1100 may supply power so that the cartridge heater 2400 and/or the heater 1800 may be heated. In addition, the power supply 1100 may supply power necessary for operations of the sensor 1300, the output unit 1400, the input unit 1500, the communication unit 1600, and the memory 1700, which are other components provided within the aerosol generating device 1000. The power supply 1100 may be a rechargeable battery or a disposable battery. For example, the power supply 1100 may be a lithium polymer (LiPoly) battery, but is not limited thereto.

Although not shown in FIG. 10, the aerosol generating device 1000 may further include a power protection circuit. The power protection circuit may be electrically connected to the power supply 1100 and may include a switching element.

The power protection circuit may cut off an electrical path with respect to the power supply 1100 according to a certain condition. For example, the power protection circuit may cut off the electrical path with respect to the power supply 1100 when a voltage level of the power supply 1100 is a first voltage or more corresponding to overcharging. For example, the power protection circuit may cut off the electrical path with respect to the power supply 1100 when the voltage level of the power supply 1100 is less than a second voltage corresponding to overdischarging.

The heater 1800 may be supplied with power from the power supply 1100 and heat a medium or an aerosol generating material within the aerosol generating article. Although not shown in FIG. 10, the aerosol generating device 1000 may further include a power conversion circuit (e.g., a DC/DC converter) that converts power of the power supply 1100 and supplies the converted power to the cartridge heater 2400 and/or the heater 1800. In addition, when the aerosol generating device 1000 generates an aerosol by an induction heating method, the aerosol generating device 1000 may further include a DC/AC converter that converts DC power of the power supply 1100 into AC power.

The control unit 1200, the sensor 1300, the output unit 1400, the input unit 1500, the communication unit 1600, and the memory 1700 may be supplied with power from the power supply 11 to perform functions. Although not shown in FIG. 10, the aerosol generating device 1000 may further include a power conversion circuit that converts power of the power supply 1100 and supplies the power to each of components, e.g., a low-dropout (LDO) circuit or a voltage regulator circuit. In addition, although not shown in FIG. 10, a noise filter may be provided between the power supply 1100 and the heater 1800. The noise filter may be a low pass filter. The low pass filter may include at least one inductor and a capacitor. A cutoff frequency of the low pass filter may correspond to a frequency of a high-frequency switching current applied from the power supply 1100 to the heater 1800. The low pass filter may prevent a high-frequency noise component from being applied to the sensor 1300, such as the insertion detection sensor 1330.

In an embodiment, the cartridge heater 2400 and/or the heater 1800 may include any suitable electrically resistive material. For example, the suitable electrically resistive material may be a metal or a metal alloy including titanium, zirconium, tantalum, platinum, nickel, cobalt, chromium, hafnium, niobium, molybdenum, tungsten, tin, gallium, manganese, iron, copper, stainless steel, or nichrome, but is not limited thereto. In addition, the heater 1800 may be implemented by a metal wire, a metal plate on which an electrically conductive track is disposed, or a ceramic heating element, but is not limited thereto.

In another embodiment, the heater 1800 may include an induction heating-type heater. For example, the heater 1800 may include a susceptor that generates heat through a magnetic field applied by a coil to heat an aerosol generating material.

The input unit 1500 may receive information input from the user or output the information to the user. For example, the input unit 1500 may be a touch panel. The touch panel may include at least one touch sensor detecting a touch. For example, the touch sensor may include a capacitive touch sensor, a resistive touch sensor, a surface acoustic wave touch sensor, an infrared touch sensor, etc., but is not limited thereto.

The display 1410 and the touch panel may be implemented as one panel. For example, the touch panel may be inserted into the display 1410 (e.g., may be an on-cell type or in-cell type). For example, the touch panel may be added on the display 1410 (e.g., an add-on type).

Meanwhile, the input unit 1500 may include a button, a keypad, a dome switch, a jog wheel, a jog switch, etc., but is not limited thereto.

The memory 1700, which is hardware storing various types of data processed within the aerosol generating device 1000, may store pieces of data processed by the control unit 1200 and pieces of data to be processed by the control unit 1200. The memory 1700 may include at least one type of storage medium from among a flash memory type, a hard disk type, a multimedia card micro type, a card type memory (e.g., a SD or XD memory), random access memory (RAM), static random access memory (SRAM), read-only memory (ROM), electrically erasable programmable read-only memory (EEPROM), programmable read-only memory (PROM), a magnetic memory, a magnetic disk, and an optical disk. The memory 1700 may store data regarding an operation time of the aerosol generating device 1000, the maximum number of puffs, the current number of puffs, at least one temperature profile, and a smoking pattern of the user.

The communication unit 1600 may include at least one component for communication with another electronic device. For example, the communication unit 1600 may include at least one of a short-range wireless communication unit and a wireless communication unit.

The short-range wireless communication unit may include a Bluetooth communication unit, a Bluetooth low energy (BLE) communication unit, a near field communication unit, a wireless local region network ((WLAN) (Wi-Fi)) communication unit, a Zigbee communication unit, an infrared data association (IrDA) communication unit, a Wi-Fi Direct (WFD) communication unit, an ultra wideband (UWB) communication unit, an Ant+ communication unit, etc., but is not limited thereto.

The wireless communication unit may include a cellular network communication unit, an Internet communication unit, a computer network (e.g., LAN or WAN) communication unit, etc., but is not limited thereto.

Although not shown in FIG. 10, the aerosol generating device 1000 may further include a connection interface such as a universal serial bus (USB) interface, and may be connected to another external device through the connection interface such as the USB interface to transmit and receive information or charge the power supply 1100.

The control unit 1200 may control an overall operation of the aerosol generating device 1000. In an embodiment, the control unit 1200 may include at least one processor. The processor may be implemented as an array of a plurality of logic gates or may be implemented as a combination of a general-purpose microprocessor and a memory that stores a program executable by the microprocessor. In addition, one of ordinary skill in the art to which the present embodiment pertains may understand that the processor may be implemented as other types of hardware.

The control unit 1200 may control the temperature of the heater 1800 by controlling supply power from the power supply 1100 to the heater 1800. The control unit 1200 may control the temperature of the cartridge heater 2400 and/or the heater 1800 based on the temperature of the cartridge heater 2400 and/or the heater 1800 sensed by the temperature sensor 1310. The control unit 1200 may adjust power supplied to the cartridge heater 2400 and/or the heater 1800, based on the temperature of the cartridge heater 2400 and/or the heater 1800. For example, the control unit 1200 may determine a target temperature with respect to the cartridge heater 2400 and/or the heater 1800, based on a temperature profile stored in the memory 1700.

The aerosol generating device 1000 may include a power supply circuit (not shown) electrically connected to the power supply 1100 between the power supply 1100 and the cartridge heater 2400 and/or the heater 1800. The power supply circuit may be electrically connected to the cartridge heater 2400 and the heater 1800. The power supply circuit may include at least one switching element. The switching element may be implemented by a bipolar junction transistor (BJT), a field effective transistor (FET), etc. The control unit 1200 may control the power supply circuit.

The control unit 1200 may control power supply by controlling switching of the switching element of the power supply circuit. The power supply circuit may be an inverter that converts DC power output from the power supply 1100 into AC power. For example, the inverter may include a full-bridge circuit or a half-bridge circuit including a plurality of switching elements.

The control unit 1200 may turn on the switching element so that power is supplied from the power supply 1100 to the cartridge heater 2400 and/or the heater 1800. The control unit 1200 may turn off the switching element to cut off the supply of power to the cartridge heater 2400 and/or the heater 1800. The control unit 1200 may adjust a current supplied from the power supply 1100 by adjusting a frequency and/or duty ratio of a current pulse input into the switching element.

The control unit 1200 may control a voltage output from the power supply 1100 by controlling switching of the switching element of the power supply circuit. The power conversion circuit may convert the voltage output from the power supply 1100. For example, the power conversion circuit may include a buck-converter that steps down the voltage output from the power supply 1100. For example, the power conversion circuit may be implemented through a buck-boost converter, a zener diode, etc.

The control unit 1200 may adjust a level of the voltage output from the power conversion circuit by controlling an on/off operation of the switching element included in the power conversion circuit. When the switching element continues to be turned on, the level of the voltage output from the power conversion circuit may correspond to a level of a voltage output from the power supply 1100. The duty ratio for the on/off operation of the switching element may correspond to a ratio of the voltage output from the power conversion circuit to the voltage output from the power supply 1100. The level of the voltage output from the power conversion circuit may decrease as the duty ratio with respect to the on/off operation of the switching element decreases. The heater 1800 may be heated based on the voltage output from the power conversion circuit.

The control unit 1200 may control power to be supplied to the heater 1800 by using at least one of a pulse width modulation (PWM) method and a proportional-integral-differential (PID) method.

For example, the control unit 1200 may control a current pulse having a certain frequency and duty ratio to be supplied to the heater 1800 by using the PWM method. The control unit 1200 may control the power supplied to the heater 1800 by adjusting the frequency and duty ratio of the current pulse.

For example, the control unit 1200 may determine a target temperature to be controlled, based on the temperature profile. The control unit 1200 may control the power supplied to the heater 1800 by using the PID method, which is a feedback control method through a difference value between the temperature of the heater 1800 and the target temperature, a value obtained by integrating the difference value over time, and a value obtained by differentiating the difference value over time.

The control unit 1200 may prevent the cartridge heater 2400 and/or the heater 1800 from overheating. For example, on the basis that the temperature of the cartridge heater 2400 and/or the heater 1800 exceeds a preset limit temperature, the control unit 1200 may control an operation of the power conversion circuit so that the supply of power to the cartridge heater 2400 and/or the heater 1800 stops. For example, on the basis that the temperature of the cartridge heater 2400 and/or the heater 1800 exceeds the preset limit temperature, the control unit 1200 may reduce an amount of power supplied to the cartridge heater 2400 and/or the heater 1800 by a certain ratio. For example, on the basis that the temperature of the cartridge heater 2400 exceeds the preset limit temperature, the control unit 1200 may determine that the aerosol generating material accommodated in the cartridge 19 is exhausted and cut off the power supply to the cartridge heater 2400.

The control unit 1200 may control charging and discharging of the power supply 1100. The control unit 1200 may identify the temperature of the power supply 1100 based on an output signal of the temperature sensor 1310.

When a power line is connected to a battery terminal of the aerosol generating device 1000, the control unit 1200 may identify whether the temperature of the power supply 1100 is a first limit temperature or more which is a reference for blocking charging of the power supply 1100. When the temperature of the power supply 1100 is less than the first limit temperature, the control unit 1200 may control the power supply 1100 to be charged, based on a preset charging current. The control unit 1200 may block charging of the power supply 1100 when the temperature of the power supply 1100 is the first limit temperature or more.

While the power of the aerosol generating device 1000 is turned on, the control unit 1200 may identify whether the temperature of the power supply 1100 is a second limit temperature or more which is a reference for blocking discharge of the power supply 1100. The control unit 1200 may control power stored in the power supply 1100 to be used when the temperature of the power supply 1100 is less than the second limit temperature. When the temperature of the power supply 1100 is the second limit temperature or more, the control unit 1200 may stop using the power stored in the power supply 1100.

The control unit 1200 may calculate the remaining capacity of the power stored in the power supply 1100. For example, the control unit 1200 may calculate the remaining capacity of the power supply 1100 based on a voltage and/or current sensing value of the power supply 1100.

The control unit 1200 may determine, through the insertion detection sensor 1330, whether the aerosol generating article is inserted into the insertion space. The control unit 1200 may determine that the aerosol generating article is inserted, based on the output signal of the insertion detection sensor 1330. When determining that the aerosol generating article is inserted into the insertion space, the control unit 1200 may control power to be supplied to the cartridge heater 2400 and/or the heater 1800. For example, the control unit 1200 may supply power to the cartridge heater 2400 and/or the heater 1800, based on the temperature profile stored in the memory 1700.

The control unit 1200 may determine whether the aerosol generating article is removed from the insertion space. For example, the control unit 1200 may determine, through the insertion detection sensor 1330, whether the aerosol generating article is removed from the insertion space. For example, when the temperature of the heater 1800 is the preset limit temperature or more or when a temperature change gradient of the heater 1800 is a set gradient, the control unit 1200 may determine that the aerosol generating article is removed from the insertion space. When it is determined that the aerosol generating article is removed from the insertion space, the control unit 1200 may cut off the supply of power to the cartridge heater 2400 and/or the heater 1800.

The control unit 1200 may control a power supply time and/or a power supply amount with respect to the heater 1800, according to a state of the aerosol generating article detected by the sensor 1300. The control unit 1200 may identify, based on a look-up table, a level range including a level of a signal of the capacitance sensor. The control unit 1200 may determine an amount of moisture in the aerosol generating article, according to the identified level range.

When the aerosol generating article is over-humidified, the control unit 1200 may increase a preheating time of the aerosol generating article compared to a normal state by controlling the power supply time with respect to the heater 1800.

The control unit 1200 may determine, through the reuse detection sensor 1340, whether the aerosol generating article inserted into the insertion space is reused. For example, the control unit 1200 may compare a sensing value of a signal of the reuse detection sensor 1340 with a first reference range including a first color and when the sensing value is included in the first reference range, determine that the aerosol generating article is not used. For example, the control unit 1200 may compare the sensing value of the signal of the reuse detection sensor 1340 with a second reference range including a second color and when the sensing value is included in the second reference range, determine that the aerosol generating article is used. When it is determined that the aerosol generating article is used, the control unit 1200 may cut off the supply of power to the cartridge heater 2400 and/or the heater 1800.

The control unit 1200 may determine, through the cartridge detection sensor 1350, whether the cartridge 19 is coupled and/or removed. For example, the control unit 1200 may determine whether the cartridge 19 is coupled or removed, based on a sensing value of the signal of the cartridge detection sensor 1350.

The control unit 1200 may determine whether the aerosol generating material of the cartridge 19 is exhausted. For example, the control unit 1200 may apply power to preheat the cartridge heater 2400 and/or the heater 1800, determine whether the temperature of the cartridge heater 2400 exceeds the limit temperature in a preheating period, and when the temperature of the cartridge heater 2400 exceeds the limit temperature, determine that the aerosol generating material of the cartridge 19 is exhausted. When it is determined that the aerosol generating material of the cartridge 19 is exhausted, the control unit 1200 may cut off the supply of power to the cartridge heater 2400 and/or the heater 1800.

The control unit 1200 may determine whether the cartridge 19 may be used. When the current number of puffs is greater than or equal to the maximum number of puffs set in the cartridge 19, the control unit 1200 may determine, based on the data stored in the memory 1700, that the cartridge 19 may not be used. For example, when the total time for which the cartridge heater 2400 is heated is a preset maximum time or more or the total amount of power supplied to the cartridge heater 2400 is a preset maximum amount of power or more, the control unit 1200 may determine that the cartridge 19 may not be used.

The control unit 1200 may determine inhalation by the user through the puff sensor 1320. For example, the control unit 1200 may determine whether a puff occurs, based on a sensing value of a signal of the puff sensor 1320. For example, the control unit 1200 may determine an intensity of the puff, based on the sensing value of the signal of the puff sensor 1320. When the number of puffs reaches the preset maximum number of puffs or when puffs are not detected for a preset time or more, the control unit 1200 may cut off the supply of power to the cartridge heater 2400 and/or the heater 1800.

The control unit 1200 may determine, through the cap detection sensor 1360, whether a cap is coupled and/or removed. For example, the control unit 1200 may determine whether the cap is coupled and/or removed, based on a sensing value of a signal of the cap detection sensor 1360.

The control unit 1200 may control the output unit 1400 based on the result of detection by the sensor 1300. For example, when the number of puffs counted through the puff sensor 1320 reaches a preset number, the control unit 1200 may notify the user that the aerosol generating device 1000 is soon terminated, through at least one of the display 1410, the haptic unit 1420, or the sound output unit 1430. For example, the control unit 1200 may notify the user through the output unit 1400, based on the determination that the aerosol generating article is not present in the insertion space. For example, the control unit 1200 may notify the user through the output unit 14, based on the determination that the cartridge 19 and/or the cap are not mounted. For example, the control unit 1200 may transmit information about the temperature of the cartridge heater 2400 and/or the heater 1800 to the user through the output unit 1400.

The control unit 1200 may store and update, in the memory 1700, a history of a certain event that occurs, based on the occurrence of the event. The event may include detection of insertion of the aerosol generating article, initiation of heating of the aerosol generating article, detection of puffs, termination of the puffs, detection of overheating of the cartridge heater 2400 and/or the heater 1800, detection of application of an overvoltage to the cartridge heater 2400 and/or the heater 1800, termination of heating of the aerosol generating article, an operation such as power on/off of the aerosol generating device 1000, initiation of charging of the power supply 1100, detection of overcharging of the power supply 1100, termination of charging of the power supply 1100, etc. The history of the event may include a date and time when the event occurs, log data corresponding to the event, etc. For example, when the certain event is the detection of insertion of the aerosol generating article, the log data corresponding to the event may include data regarding the sensing value of the insertion detection sensor 1330. For example, when the certain event is the detection of overheating of the cartridge heater 2400 and/or the heater 1800, the log data corresponding to the event may include data regarding the temperature of the cartridge heater 2400 and/or the heater 1800, the voltage applied to the cartridge heater 2400 and/or the heater 1800, a current flowing through the cartridge heater 2400 and/or the heater 1800, etc.

The control unit 1200 may control to form a communication link with an external device such as a mobile terminal of the user. When data regarding authentication is received from the external device through the communication link, the control unit 1200 may release a restriction on use of at least one function of the aerosol generating device 1000. Here, the data regarding the authentication may include data indicating completion of user authentication with respect to the user corresponding to the external device. The user may perform the user authentication through the external device. The external device may determine whether user data is valid, based on the birthday of the user, a unique number indicating the user, etc. and receive, from an external server, data regarding use authority over the aerosol generating device 1000. The external device may transmit the data indicating the completion of the user authentication to the aerosol generating device 1000, based on the data regarding the use authority. When the user authentication is completed, the control unit 1200 may release the restriction on the use of at least one function of the aerosol generating device 1000. For example, when the user authentication is completed, the control unit 1200 may release a restriction on use of a heating function of supplying power to the heater 1800.

The control unit 1200 may transmit data regarding the state of the aerosol generating device 1000 to the external device through the communication link formed with the external device. Based on the received data regarding the state, the external device may output the remaining capacity of the power supply 1100 of the aerosol generating device 1000, an operation mode, etc. through a display of the external device.

The external device may transmit a location search request to the aerosol generating device 1000, based on an input for initiating a location search of the aerosol generating device 1000. When receiving the location search request from the external device, the control unit 1200 may control at least one of output devices to perform an operation corresponding to the location search, based on the received location search request. For example, the haptic unit 1420 may generate vibration in response to the location search request. For example, the display 1410 may output an object corresponding to the location search and an end of the search in response to the location search request.

When receiving firmware data from the external device, the control unit 1200 may control to perform a firmware update. The external device may identify a current version of firmware of the aerosol generating device 1000 and determine whether a new version of the firmware is present. When an input for requesting firmware download is received, the external device may receive a new version of firmware data and transmit the new version of firmware data to the aerosol generating device 1000. When receiving the new version of firmware data, the control unit 1200 may control the firmware update of the aerosol generating device 1000 to be performed.

The control unit 1200 may transmit data regarding a sensing value of at least one sensor 1300 to the external server (not shown) through the communication unit 16, and receive from the server and store a learning model generated by learning the sensing value through machine learning such as deep learning. The control unit 1200 may perform an operation of determining an inhalation pattern of the user, an operation of generating a temperature profile, etc. by using the learning model received from the server. The control unit 1200 may store, in the memory 1700, sensing value data of at least one sensor 1300, data for training an artificial neural network (ANN), etc. For example, the memory 1700 may store a database with respect to each component provided in the aerosol generating device 1000, which is for training the ANN, and weights and biases constituting the structure of the ANN. The control unit 1200 may generate at least one learning model used for determining the inhalation pattern of the user, generating the temperature profile, etc., by learning data regarding the sensing value of the at least one sensor 13, the inhalation pattern of the user, the temperature profile, etc. which are stored in the memory 1700.

The descriptions of the above-described embodiments are merely examples, and it will be understood by one of ordinary skill in the art that various changes and equivalents thereof may be made. Therefore, the scope should be defined by the appended claims, and all differences within the scope equivalent to those described in the claims will be construed as being included in the scope of protection defined by the claims.

The embodiments described above, or other embodiments, are not mutually exclusive or distinct from each other. The embodiments of the disclosure described above, or other embodiments, may be used in combination or have their respective configurations or functions integrated.

For example, this means that the A configuration described in a particular embodiment and/or drawing may be combined with the B configuration described in another embodiment and/or drawing. That is, even though a combination of configurations is not explicitly described, it means that the combination is possible unless it is explicitly stated that such a combination is impossible.

The above detailed description should not be construed as limiting in any way but should be considered as illustrative. The scope of the disclosure should be determined by the reasonable interpretation of the appended claims, and all modifications within the equivalent scope of the disclosure are included in the scope of the disclosure.

Various embodiments may compensate for a detection value obtained through the sensor according to an operating environment of the sensor detecting whether the aerosol generating article is inserted.

Various embodiments may compensate for a detection value according to an operating temperature or humidity of the sensor detecting whether the aerosol generating article is inserted, thereby improving the operational reliability of the aerosol generating device.

What is claimed is:

1. An aerosol generating device comprising:
a cavity into which an aerosol generating article is inserted;
an article detection sensor configured to detect a change in capacitance of the cavity and output a signal;
a heater configured to heat at least a part of the aerosol generating article inserted into the cavity; and
a control unit electrically connected to the article detection sensor and the heater,
wherein the control unit is configured to:
compare the signal output from the article detection sensor with a preset reference value and generate a detection value; and
determine that the aerosol generating article is inserted into the cavity when the detection value is included within a preset range.

2. The aerosol generating device of claim 1, further comprising: a temperature sensor configured to detect an ambient temperature around the article detection sensor,
wherein the control unit is electrically connected to the temperature sensor to obtain the ambient temperature of the article detection sensor from the temperature sensor, and configured to compensate for the detection value, based on the ambient temperature of the article detection sensor, and determine that the aerosol generating article is inserted into the cavity when the compensated detection value is included within a preset range.

3. The aerosol generating device of claim 2, further comprising: a memory storing a compensation value for compensating for the detection value,
wherein the control unit is configured to, when the signal output from the article detection sensor is obtained, identify a temperature at a time when the signal is obtained, extract a compensation value corresponding to the temperature from the memory, and compensate for the detection value based on the extracted compensation value.

4. The aerosol generating device of claim 3, wherein the compensation value is a compensation value of the signal output from the article detection sensor according to the temperature.

5. The aerosol generating device of claim 4, wherein the compensation value ensures that a capacitance value of the cavity detected by the article detection sensor remains lower than the reference value while the aerosol generating article is not inserted into the cavity.

6. The aerosol generating device of claim 3, wherein the compensation value is a compensation value of the reference value output from the article detection sensor according to the temperature.

7. The aerosol generating device of claim 2, wherein the temperature sensor is a thin-film temperature sensor.

8. The aerosol generating device of claim 7, wherein
the article detection sensor includes a capacitive sensor including at least one electrode, and
the temperature sensor is attached to the at least one electrode.

9. The aerosol generating device of claim 8, wherein the temperature sensor includes a base attached to the at least one electrode;
a first electrode formed on the base;
a thermistor layer formed over the first electrode and the base; and
a second electrode formed over the thermistor layer and the base.

10. The aerosol generating device of claim 1, wherein the signal includes at least one of a voltage change signal, a frequency change signal, or a change signal of a charge/discharge time.

11. The aerosol generating device of claim 1, wherein
the control unit is configured to set a preheating temperature profile for the heater, based on the signal output from the article detection sensor; and supply power to the heater according to the set preheating temperature profile.

12. The aerosol generating device of claim 3, further comprising: a humidity sensor configured to detect humidity around the article detection sensor,
wherein the control unit is electrically connected to the humidity sensor to obtain the ambient temperature of the article detection sensor from the humidity sensor, and configured to, when the signal output from the article detection sensor is obtained, identify a humidity at a time when the signal is obtained, extract a compensation value corresponding to the temperature and the humidity from the memory, and compensate for the detection value based on the extracted compensation value.

13. The aerosol generating device of claim 12, wherein the compensation value is a compensation value of the signal output from the article detection sensor according to the temperature and the humidity.

14. The aerosol generating device of claim 12, wherein the compensation value is a compensation value of the reference value output from the article detection sensor according to the temperature and the humidity.

15. The aerosol generating device of claim 12, wherein
the article detection sensor includes a capacitive sensor including at least one electrode, and
the humidity sensor is a thin-film humidity sensor, and attached to the at least one electrode.
